(19) United States
(12) Patent Application Publication
(10) Pub. No.: US 2011/0027973 A1
(43) Pub. Date: Feb. 3, 2011

(54) METHOD OF FORMING LED STRUCTURES

(75) Inventors: Jie Su, Santa Clara, CA (US); Olga Kryliouk, Sunnyvale, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(73) Assignee: Applied Materials, Inc., Santa Clara, CA (US)

(21) Appl. No.: 12/842,883

(22) Filed: Jul. 23, 2010

Related U.S. Application Data
(60) Provisional application No. 61/230,567, filed on Jul. 31, 2009.

(51) Int. Cl. H01L 21/20

(52) U.S. Cl. 438/478; 257/E21.09

(57) ABSTRACT

One embodiment of fabricating a p-down light emitting diode (LED) structure comprises depositing a high crystal quality p type contact layer, depositing an active region on top of the p type contact layer, and depositing an n type contact layer on top of the active region using a hydride vapor phase epitaxy (HVPE) process. The high crystal quality p type contact layer is deposited at high temperature to ensure the high crystal quality of the p type film. The n type contact layer is formed on top of the active region in a HVPE chamber at a low temperature to prevent thermal damage to the quantum wells in the active region below the n type contact layer. The processing chamber used to form the p type contact layer is a separate processing chamber than the processing chamber used to form the n type contact layer.

This Application claims the benefit of and priority to Provisional Application Ser. No. 61/230,567, filed Jul. 31, 2009 which is hereby incorporated by reference.

### BACKGROUND OF THE INVENTION

1. Field of the Invention

Embodiments of the present invention relate to use of a cluster tool for the growth of LED structures.

2. Discussion of Related Art

Light emitting diodes (LEDs) are the ultimate light source in lighting technology. The LED technology has flourished for the past few decades. High efficiency, reliability, rugged construction, low power consumption, and durability are among the key factors for the rapid development of the solid-state lighting based on high-brightness visible LEDs. Conventional light sources, such as filament light bulbs or fluorescent lamps depend on either incandescence or discharge in gases. These two processes are accompanied by large energy losses, which are attributed to high temperatures and large Stokes shift characteristics. On the other hand, semiconductors allow an efficient way of light generation. LEDs made of semiconductor materials have the potential of converting electricity to light with near unity efficiency.

An example of a conventional n-down light emitting diode (LED) structure is illustrated in FIG. 1A. N-down LED structure 100 includes a substrate 102 having an active region 106 sandwiched between an n type contact layer 104 and a p type contact layer 108 with the n type contact layer 104 below the active region 106 and the p type contact layer 108 above the active region 106. The active region 106 generally comprises a plurality of active layers 120 including one or more quantum well layers 124 and one or more barrier layers 122. FIG. 1B illustrates an example of a p-down LED structure 140. The p-down LED structure includes a substrate 102 having an active region 106 sandwiched between a p type contact layer 108 and an n type contact layer 104 with the p type contact layer 108 below the active region 106 and the n type contact layer 104 above the active region 106.

For conventional LEDs, the n-down structure has been adopted for several reasons. Generally, the crystal quality of the n type contact layers is better than p type contact layers. Thus, active layers deposited on high crystal quality n type contact layers result in high crystal quality active layers. Additionally, the conductivity of n type contact layers is higher than that of p type contact layers. A higher conductivity level allows for better current spreading resulting in a lower turn-on voltage. Hence, the n-down structure allows for high crystal quality active layers and better current spreading in the bottom of the n-down LED structure. Consequently, the low conductivity level and low crystal quality of p type contact layers must be overcome to adopt a p-down LED structure.

### SUMMARY

One embodiment of fabricating a p-down light emitting diode (LED) structure comprises depositing a high crystal quality p type contact layer, depositing an active region on top of the p type contact layer, and depositing an n type contact layer on top of the active region using a hydride vapor phase epitaxy (HVPE) process. The high crystal quality p type contact layer is deposited at high temperature to ensure the high crystal quality of the p type film. The n type contact layer is formed on top of the active region in a HVPE chamber at a low temperature to prevent thermal damage to the quantum wells in the active region below the n type contact layer. The processing chamber used to form the p type contact layer is a separate processing chamber than the processing chamber used to form the n type contact layer.

### BRIEF DESCRIPTION OF THE DRAWINGS

FIG. 1A is an illustration of a conventional n-down light emitting diode (LED) structure.

FIG. 1B is an illustration of a p-down LED structure.

FIG. 2 is an illustration of a p-down LED structure in accordance with an embodiment of the present invention.

FIG. 3 is an illustration of a p-down LED structure with a tunnel junction in accordance with an embodiment of the present invention.

FIG. 4 is an illustration of a n-down LED structure with a tunnel junction in accordance with an embodiment of the present invention.

FIG. 5 is an isometric view illustrating a processing system according to an embodiment of the invention.

FIG. 6 is a plan view of the processing system illustrated in FIG. 7.

FIG. 7 is an isometric view illustrating a load station and loadlock chamber according to an embodiment of the invention.

FIG. 8 is a schematic view of a loadlock chamber according to an embodiment of the invention.

FIG. 9 is an isometric view of a carrier plate according to an embodiment of the invention.

FIG. 10 is a schematic view of a batch loadlock chamber according to an embodiment of the invention.

FIG. 11 is an isometric view of a work platform according to an embodiment of the invention.

FIG. 12 is a plan view of a transfer chamber according to an embodiment of the invention.

FIG. 13 is a schematic cross-sectional view of a HVPE chamber according to an embodiment of the invention.

FIG. 14 is a schematic cross-sectional view of an MOCVD chamber according to an embodiment of the invention.

FIG. 15 is a schematic view illustrating another embodiment of a processing system for fabricating compound nitride semiconductor devices.

FIG. 16 is a schematic view illustrating yet another embodiment of a processing system for fabricating compound nitride semiconductor devices.

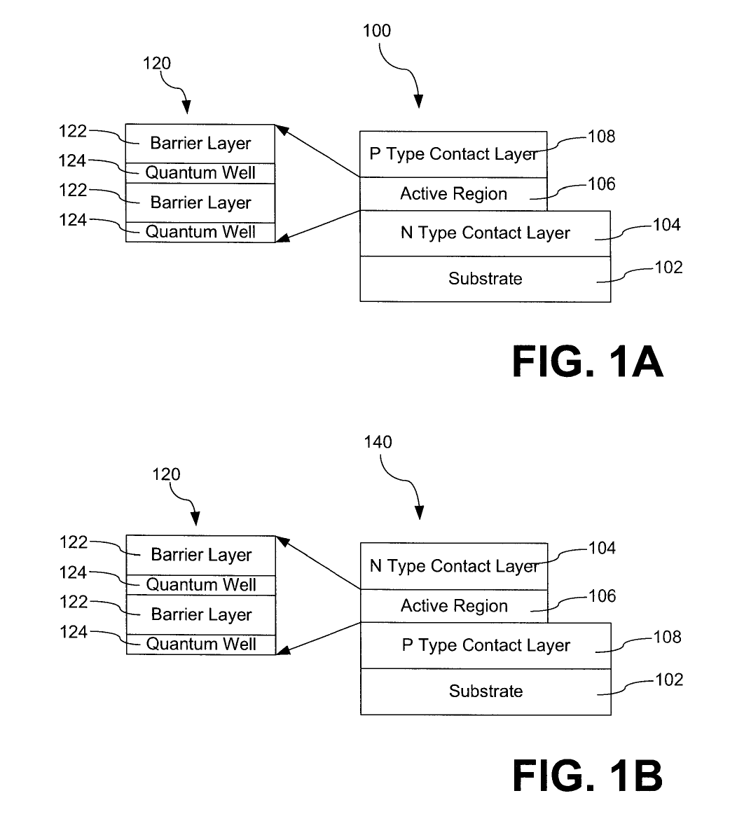

### DETAILED DESCRIPTION

Embodiments of the present invention improve the crystal quality and current spreading of a p type contact layer in light emitting diode (LED) semiconductor devices. The present invention has been described with respect to specific details in order to provide a thorough understanding of the invention. One of ordinary skill in the art will appreciate that the invention can be practiced without these specific details. In other instances, well known semiconductor processes and equipment have not been described in specific detail in order to not unnecessarily obscure the present invention.

Embodiments of the present invention improve the crystal quality and current spreading of a p type contact layer in light emitting diode (LED) semiconductor devices. The crystal quality of a p type contact layer can be improved by using a metal organic chemical vapor deposition (MOCVD) process or a hydride vapor phase epitaxy (HVPE) at high temperature to deposit a high crystal quality p type contact layer in accordance with embodiments of the present invention. In a p-down LED structure, the high crystal quality p type contact layer results in high crystal quality active layers deposited on top of the p type contact layer. Additionally, the high crystal quality p type contact layer can be formed at high temperature in a p-down structure before the active region is formed to avoid thermal damage to the quantum wells in the active region in accordance with an embodiment of the present invention. In an embodiment of the present invention, the current spreading of a p type contact layer is improved by forming a tunnel junction in contact with the p type contact layer. The tunnel junction can provide a low resistivity contact to the p type contact layer resulting in a lower turn-on voltage for the LED device. In embodiments of the present invention, the tunnel junction can be formed in contact with the p type contact layer in a p-down LED structure or in an n-down LED structure.

In embodiments of the present invention, the LED device is fabricated in a cluster tool having one or multiple processing chambers including a metal organic chemical vapor deposition (MOCVD) chamber and hydride vapor phase epitaxial (HVPE) deposition chamber and/or a plasma assisted MOCVD chamber. A substrate can be transferred between the processing chambers of the cluster tool without breaking vacuum in accordance with an embodiment of the present invention. In this way, a high crystal quality p type contact layer can be formed by a MOCVD process in the MOCVD chamber or by a HVPE process in the HVPE chamber and n type contact layer can be formed by HVPE in the HVPE chamber or by MOCVD in the MOCVD chamber.

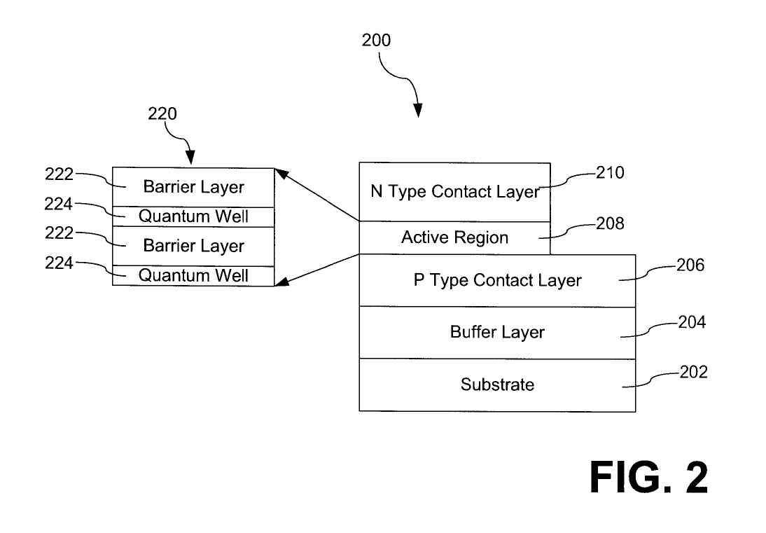

FIG. 2 illustrates a p-down LED structure 200 in accordance with an embodiment of the present invention. P-down LED structure 200 includes a bulk substrate 202. Bulk substrate may be any suitable substrate, such as but not limited to a sapphire (Al₂O₃) substrate, a silicon substrate, a silicon carbide (SiC) substrate, a silicon on diamond (SOD) substrate, a quartz substrate, a glass substrate, a silicon (Si) substrate, a zinc oxide (ZnO) substrate, a magnesium oxide (MgO) substrate, a gallium nitride (GaN) substrate, a lithium aluminum oxide (LiAlO₂) substrate, and a lithium gallium oxide (LiGaO₂) substrate. Additionally, substrate 202 may be a planar substrate or have patterned features therein. An optional buffer or transition layer 204 may be formed on the substrate 202. Buffer/transition layer 204 provides a buffer or transition between the substrate 202 and the subsequently formed device layers of the LED structures. In a specific embodiment of the present invention, the buffer/transition layer can comprise, for example, an undoped gallium nitride (GaN) film.

Next, a p type contact layer 206 is formed on the buffer/transition layer. P type contact layer 206 can be any suitable III-V semiconductor material, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, p type contact layer 206 can be single crystalline or polycrystalline. In a specific embodiment of the present invention, p type contact layer 206 is single crystalline. P type contact layer 206 can be doped with any suitable p type dopant to a p type conductively level between 1×10¹⁷ atoms/cm³ and 1×10²⁰ atoms/cm³ and can be formed to a thickness of approximately 0.1 μm to 4.0 μm. The p type dopant can be any suitable p type dopant such as but not limited to Mg, Be, Ca, Sr, or any suitable Group I or Group II element having at least two valence electrons. In a specific embodiment of the present invention, the p type contact layer 206 is a magnesium doped gallium nitride (Mg—GaN) film.

In embodiments of the present invention, p type contact layer 206 can be formed at high temperature using a metal organic chemical vapor deposition (MOCVD) process in a MOCVD chamber or using a hydride vapor phase epitaxy (HVPE) process in a HVPE chamber. In a specific embodiment of the present invention, p type contact layer is formed by a MOCVD process in a MOCVD chamber using a p type dopant containing precursor, such as biscyclopentadienyl magnesium (Cp₂Mg). In p-down LED structure 200, the p type contact layer 206 is formed before the active region 208. In this way, a high crystal quality p type contact layer can be formed at high temperature without causing thermal damage to the quantum wells 224 in active region 208. In an embodiment of the present invention, the substrate 202 is heated to a temperature greater than 1000° C. to ensure the deposition of a high crystal quality p type film. The chamber can be maintained at a pressure between 100 torr to 760 torr. In an embodiment of the present invention, the MOCVD chamber or HVPE chamber used to form p type contact layer 206 is one processing chamber on a cluster tool with one or multiple processing chambers.

Additionally, in embodiments of the present invention an electron blocking layer (not shown in FIG. 2) can be formed on p type contact layer 206. The electron blocking layer can be formed from any suitable III-V compound semiconductor, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), aluminum gallium nitride (AlGaN), and aluminum gallium indium phosphide (AlGaInP). In embodiments of the present invention, electron blocking layer can be single crystalline or polycrystalline. In a specific embodiment of the present invention, electron blocking layer is single crystalline. The electron blocking layer can help confine the radiative recombination within the active region. The electron blocking layer can be doped with any suitable p type dopant and has a band gap that is higher than the bandgap of the quantum wells and barrier layers in an embodiment of the present invention. The p type dopant can be any suitable p type dopant such as but not limited to Mg, Be, Ca, Sr, or any suitable Group I or Group II element having at least two valence electrons. In a specific embodiment of the present invention, the electron blocking layer is a magnesium doped aluminum gallium nitride (Mg—AlGaN) layer. The electron blocking layer can be formed using either a HVPE process in a HVPE chamber or a MOCVD process in a MOCVD chamber.

An active region 208 is formed on p type contact layer 206. In an embodiment of the present invention, active region 208 comprises a plurality of active layers 220. The active layers 220 can comprise one or multiple quantum wells 224 and one or more barrier layers 222. In an embodiment of the present invention, active region 208 includes between 10 to 20 stacks of barrier layers 222 and quantum wells 224. Quantum wells 224 and barrier layers 222 may be formed from any suitable III-V semiconductor material such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, quantum wells 224 and barrier layers 222 can be single crystalline or polycrystalline. In a specific embodiment of the present invention, quantum wells 224 and barrier layers 222 are single crystalline. Quantum wells 224 are formed from a III-V semiconductor material having a band gap which is less than the band gap of a III-V semiconductor material used to form the barrier layers 222 so that the barrier layers 222 can confine the carriers within the wells. Additionally, it is to be appreciated that typically all of the barrier layers 222 are formed of the same semiconductor material and all of the quantum wells 224 are formed of the same semiconductor material. In a specific embodiment of the present invention, the active region 208 is made up of a plurality of magnesium doped gallium nitride (Mg—GaN) barrier layers 222 and a plurality of indium gallium nitride (InGaN) quantum wells 224. Generally, the type of semiconductor material chosen for the quantum wells 224 determines the frequency of the radiation emitted from the LED. The active layers 220 can be formed using either a HVPE process in a HVPE chamber or a MOCVD process in a MOCVD chamber.

Finally, an n type contact layer 210 is formed on the active region. N type contact layer 210 can be any n type doped III-V semiconductor material, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, n type contact layer 210 can be single crystalline or polycrystalline. In a specific embodiment of the present invention, n type contact layer 210 is single crystalline. N type contact layer 210 can be doped with any suitable n type dopant such as but not limited to Si, Ge, Sn, Pb, or any suitable Group IV, Group V, or Group VI element. In embodiments of the present invention, n type contact layer 210 is generally doped with silicon (Si) to a conductivity level of between 1×10¹⁸ atoms/cm³ and 1×10²⁰ atoms/cm³. In a specific embodiment of the present invention, the n type contact layer 210 is a silicon doped gallium nitride film (Si—GaN). Additionally, n type contact layer 210 can be formed to a thickness between 0.1 μm and 4.0 μm.

In an embodiment of the present invention, n type contact layer 210 is grown at a low temperature by a hydride vapor phase epitaxy (HVPE) process in a HVPE chamber. In an embodiment of the present invention, the substrate 202 is heated to a temperature less than 950° C. to avoid thermal damage to the quantum wells 224 below the n type contact layer 210. The chamber can be maintained at a pressure between 100 torr and 760 torr. In an embodiment of the present invention, the HVPE chamber used to form n type contact layer 210 is one processing chamber on a cluster tool with one or multiple processing chambers. In an embodiment of the present invention, the processing chamber used to form n type contact layer 210 is a separate processing chamber on the cluster tool than the processing chamber used to form p type contact layer 206 described above. It is to be appreciated that a substrate can be transferred from the processing chamber used to form the p type contact layer 206 to the processing chamber used to form n type contact layer 210 without breaking vacuum.

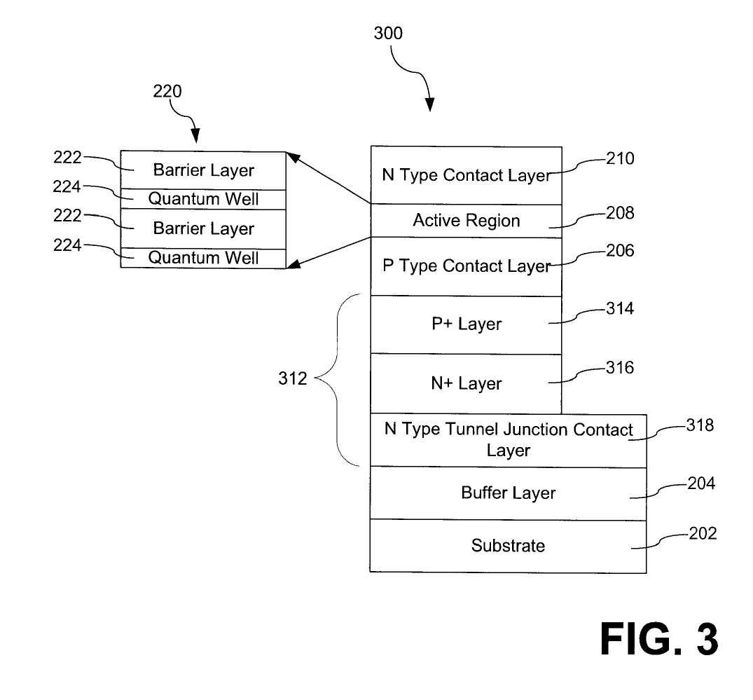

FIG. 3 illustrates an embodiment of the present invention similar to the p-down LED structure 200 described above. P-down LED structure 300 includes a bulk substrate 202, a buffer/transition layer 204, a tunnel junction 312, a p type contact layer 206, an active region 208, and an n type contact layer 210. Active region 208 is sandwiched between the p type contact layer 206 and the n type contact layer 210 with the p type contact layer 206 below the active region 208 and the n type contact layer 210 above the active region 208. In an embodiment of the present invention an electron blocking layer (not shown in FIG. 3) can be formed between the p type contact layer 206 and the active region 208. In an embodiment of the present invention, tunnel junction 312 is formed below p type contact layer 206. Tunnel junction 312 can provide a low resistivity contact to the p type contact layer 206 allowing for better current spreading in the bottom of the p-down structure which allows for a lower turn-on voltage for the LED device in accordance with an embodiment of the present invention.

In an embodiment of the present invention, the tunnel junction 312 can be formed by forming a p-n junction with thin degenerate layers (highly doped thin p type or n type layers with a thickness between 1 nm and 20 nm and doped to a conductivity level greater than 1×10¹⁹ atoms/cm³). Tunnel junction 312 comprises an n type tunnel junction contact layer 318, p+ layer 314, and an n+ layer 316 in an embodiment of the present invention. An abrupt p+/n+ doping profile can be formed in tunnel junction 312 between the p+ layer and the n+ layer by growing the n+ layer and the p+ layer in separate chambers in accordance with an embodiment of the present invention. In another embodiment of the present invention, tunnel junction 312 can comprise a thin insulating layer, such as aluminum nitride (AlN) or any other suitable dielectric material, with a thickness between 1 nm and 20 nm.

In an embodiment of the present invention, n type tunnel junction contact layer 318 is formed on the buffer/transition layer 204. N type tunnel junction contact layer 318 can be any suitable n type doped III-V semiconductor material, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, n type tunnel junction contact layer 318 can be single crystalline or polycrystalline. In a specific embodiment of the present invention, n type tunnel junction contact layer 318 is single crystalline. The n type dopant can be any suitable n type dopant such as but not limited to Si, Ge, Sn, Pb, or any suitable Group IV, Group V, or Group VI element. N type tunnel junction contact layer 318 can be formed using either a HVPE process in a HVPE chamber or a MOCVD process in a MOCVD chamber. In a specific embodiment, n type tunnel junction contact layer 318 is gallium nitride (GaN) film doped with an n type dopant, such as silicon (Si), to a conductivity level between 1×10¹⁸ atoms/cm³ and 1×10²° atoms/cm³.

In an embodiment of the present invention, n+ layer 316 is formed on top of n type tunnel junction contact layer 318. N+ layer 316 can be any suitable n type doped III-V semiconductor material, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, n+ layer 316 can be single crystalline or polycrystalline. In a specific embodiment of the present invention, n+ layer 316 is single crystalline. The n type dopant can be any suitable n type dopant such as but not limited to Si, Ge, Sn, Pb, or any suitable Group IV, Group V, or Group VI element. In an embodiment of the present invention, n+ layer 316 is between 1 nm and 20 nm thick. In a specific embodiment of the present invention, n+ layer 316 is gallium nitride (GaN) film doped with any suitable n type dopant, such as silicon (Si), to a conductivity level greater than 1×10″ atoms/cm³. N+ layer 316 can be formed using either a HVPE process in a HVPE chamber or a MOCVD process in a MOCVD chamber.

In an embodiment of the present invention, p+ layer 314 is formed on top of the n+ layer 316. P+ layer 314 can be any suitable n type doped III-V semiconductor material, such as but not limited to gallium nitride (GaN), gallium arsenide (GaAs), gallium phosphide (GaP), gallium arsenide phosphide (GaAsP), aluminum gallium indium phosphide (AlGaInP), indium gallium nitride (InGaN), and aluminum gallium indium phosphide (AlGaInP). In embodiments of the present invention, p+ layer 314 can be single crystalline or polycrystalline. In a specific embodiment of the present invention, p+ layer 314 is single crystalline. The p type dopant can be any suitable p type dopant such as but not limited to Mg, Be, Ca, Sr, or any suitable Group I or Group II element having at least two valence electrons. In an embodiment of the present invention, p+ layer 314 is between 1 nm and 20 nm thick. In a specific embodiment of the present invention, p+ layer 314 is a gallium nitride (GaN) film doped with magnesium (Mg) to a conductivity level greater than 1×10¹⁹ atoms/cm³. P+ layer 314 can be formed using either a HVPE process in a HVPE chamber or a MOCVD process in a MOCVD chamber.

P+ layer 314 is formed in contact with n+ layer 316 creating an abrupt n+/p+doping profile in accordance with an embodiment of the present invention. In an embodiment of the present invention, the abrupt n+/p+ doping profile can be achieve by forming n+ layer 316 in a separate processing chamber than the processing chamber used to form p+ layer 314. In embodiments of the present invention, the processing chamber used to form the p+ layer 314 and the processing chamber used to form n+ layer 316 are processing chambers on a cluster tool where a substrate can be transferred between the cluster tool processing chambers without breaking vacuum.

In an embodiment of the present invention, p type contact layer 206 is formed on p+ layer 314. P type contact layer 206 can be formed using either a MOCVD process in a MOCVD chamber or a HVPE process in a HVPE chamber. P type contact layer 206 is formed in contact with p+ layer 314 creating an abrupt p/p+ doping profile in accordance with an embodiment of the present invention. In a specific embodiment of the present invention, the abrupt p/p+ doping profile can be achieved by forming the p type contact layer 206 and the p+ layer 314 with a hydride vapor phase epitaxial (HVPE) process in a HVPE chamber. The chamber can be maintained at a pressure between 100 torr to 760 torr. A HVPE process does not use biscyclopentadienyl magnesium (Cp₂Mg) as the source for the p type dopant. Cp₂Mg can cause a turn-on delay and memory effect that may contaminate subsequent device layers with magnesium. Using a HVPE process to form p type contact layer 206 in contact with p+ layer 314 avoids the memory effect and turn-on delay associated with Cp₂Mg and results in an abrupt p/p+ doping profile in accordance with an embodiment of the present invention. In a specific embodiment of the present invention, a magnesium doped gallium nitride (Mg—GaN) p+ layer 314 and a magnesium doped gallium nitride (Mg—GaN) p type contact layer 206 are formed by a HVPE process using a magnesium gallium (MgGa) eutectic alloy as a source. HCl or chlorine gas (Cl₂) is then reacted with the magnesium gallium (MgGa) eutectic alloy to form gaseous magnesium chloride (MgCl) and gallium chloride (GaCl or GaCl₃). In another embodiment of the present invention, magnesium and gallium can be provide as separate sources. In an embodiment of the present invention, the abrupt p/p+ doping profile can be achieve by forming p type contact layer 206 in a separate processing chamber than the processing chamber used to form p+ layer 314. In embodiments of the present invention, the processing chamber used to form the p type contact layer 206 and the processing chamber used to form p+ layer 314 are processing chambers on a cluster tool where a substrate can be transferred between the cluster tool processing chambers without breaking vacuum.

In an embodiment of the present invention, active region 208 is formed on top of p type contact layer 206. Active region 208 can be formed using either a HVPE process in a HVPE chamber or a MOCVD process in a MOCVD chamber. In an embodiment of the present invention, n type contact layer 210 is formed on top of active region 208. N type contact layer 210 can be formed using either a MOCVD process in a MOCVD chamber or a HVPE process in a HVPE chamber. In a specific embodiment of the present invention, n type contact layer 210 is grown at a low temperature by a HVPE process in a HVPE chamber. In an embodiment of the present invention, the substrate 202 is heated to a temperature less than 950° C. to avoid thermal damage to the quantum wells 224 below the n type contact layer 210. The chamber can be maintained at a pressure between 100 torr and 760 torr.

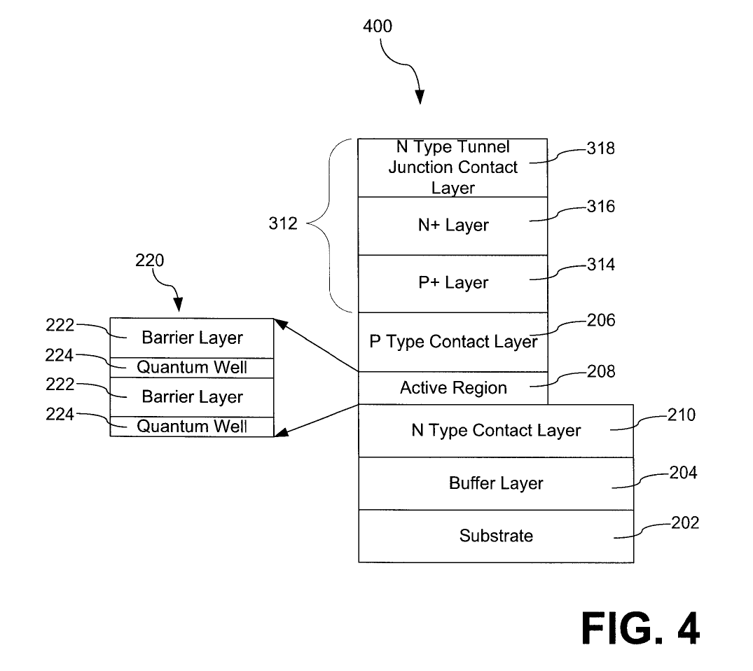

In another embodiment of the present invention, FIG. 4 illustrates a n-down LED structure 400. LED structure 400 includes a bulk substrate 202, a buffer/transition layer 204, an n type contact layer 210, an active region 208, a p type contact layer 206, and a tunnel junction 312. In one embodiment of the present invention, n-down LED structure 400 is formed with the active region 208 sandwiched between the n type contact layer 210 and the p type contact layer 206 with the n type contact layer 210 below the active region 208 and the p type contact layer 206 above the active region 208. In an embodiment of the present invention, an electron blocking layer (not shown in FIG. 4) can be formed between active region 208 and p type contact layer 206. Tunnel junction 312 is formed on top of the p type contact layer 206 in accordance with an embodiment of the present invention. Tunnel junction 312 provides a low resistivity contact to the p type contact layer 206 which can reduce the turn on voltage of the n-down LED device in accordance with an embodiment of the present invention.

In an embodiment of the present invention, n type contact layer 210 is formed on buffer/transition layer 204 using either a HVPE process in a HVPE chamber or a MOCVD process in a MOCVD chamber. In an embodiment of the present invention, active region 208 is formed on top of the n type contact layer 210. Active region 208 can be formed using either a HVPE process in a HVPE chamber or a MOCVD process in a MOCVD chamber.

P type contact layer 206 is formed on top of the active region 208 in one embodiment of the present invention. In another embodiment of the present invention, an electron blocking layer (not shown in FIG. 4) is formed on top of active region 208 and p type contact layer 206 is formed on top of the electron blocking layer. In an embodiment of the present invention, p type contact layer 206 can be grown at a low temperature by a HVPE process in a HVPE chamber or by a MOCVD process in a MOCVD chamber. In a specific embodiment, p type contact layer 206 is grown by a HVPE process in a HVPE chamber at low temperature. In an embodiment of the present invention, the substrate 202 is heated to a temperature less than 950° C. to prevent thermal damage to the quantum wells 224 below the p type contact layer 206. The chamber can be maintained at a pressure between 100 torr to 760 torr. In an embodiment of the present invention, the HVPE process uses a magnesium gallium (MgGa) eutectic alloy as a source to form a magnesium doped gallium nitride (Mg—GaN) p type contact layer 206. HCl or chlorine gas (Cl₂) is then reacted with the magnesium gallium (MgGa) eutectic alloy to form gaseous magnesium chloride (MgCl) and gallium chloride (GaCl or GaCl₃) used to form p type contact layer 206. In another embodiment of the present invention, magnesium and gallium can be provide as separate sources.

Tunnel junction 312 is formed on top of p type contact layer 206 in one embodiment of n-down LED structure 400. The tunnel junction 312 provides a low resistivity contact to p type contact layer 206 allowing for better current spreading in the top of n-down LED structure 400 and a lower turn on voltage for the n-down LED device. In an embodiment of the present invention, tunnel junction 312 comprises an n type tunnel junction contact layer 318, an n+ layer 316, and a p+ layer 314. In one embodiment of the present invention, the p+ layer 314 is formed on top of the p type contact layer 206, the n+ layer 316 is formed on top of the p+ layer 314, and the n type tunnel junction contact layer 318 is formed on top of the n+ layer 316. In embodiments of the present invention, n+ layer 316, p+ layer 314, and n type tunnel junction contact layer 318 can be formed by a HVPE process in a HVPE chamber or by a MOCVD process in a MOCVD chamber. In an embodiment of the present invention, n+ layer 316 is formed in a separate processing chamber than p+ layer 314 creating an abrupt n+/p+ doping profile. In an embodiment of the present invention, p type contact layer 206 and p+ layer 314 are formed using a HVPE process in a HVPE chamber creating an abrupt p/p+ doping profile. In an embodiment of the present invention, the processing chamber used to for p+ layer 314 is a separate processing chamber than the processing chamber used to form p type contact layer 206.

In an embodiment of the present invention, the structures described above can be formed in a cluster tool having one or multiple processing chambers, such as a MOCVD chamber, a plasma enhanced MOCVD chamber, and a HVPE chamber. In an embodiment of the present invention, the cluster tool can include any well known plasma enhanced MOCVD chamber. Additionally, in an embodiment of the present invention, the described MOCVD chamber can operate in a plasma enhanced manner by including plasma generating means in the MOCVD chamber, including a downstream plasma chamber to activate the precursor gases prior to feeding them into the deposition chamber, or including both plasma generating means in the MOCVD chamber and including a downstream plasma chamber. In embodiments of the present invention, the cluster tool can have various configurations, such as but not limited to having two MOCVD chambers and one HVPE chamber, having three MOCVD chambers and one HVPE chamber, and having one MOCVD chamber, one plasma enhanced MOCVD chamber, and one HVPE chamber. It is to be appreciated that a substrate can be transferred between the processing chambers of the cluster tool without breaking vacuum.

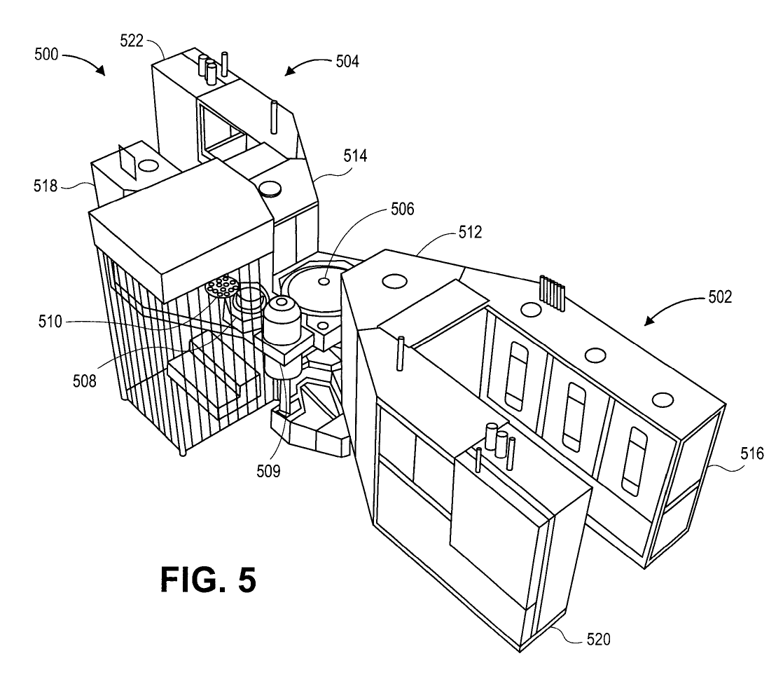

An example of a cluster tool which can be used to fabricate the LED structures in accordance with embodiments of the present invention is illustrated and described with respect to FIGS. 5-16.

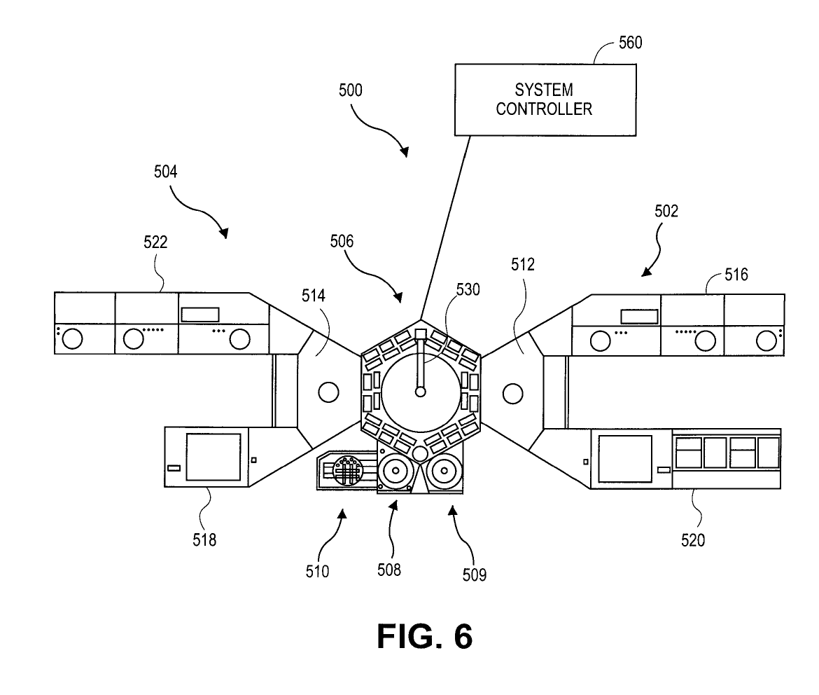

FIG. 5 is an isometric view of one embodiment of a processing system 500 that illustrates a number of aspects of the present invention that may be advantageously used. FIG. 6 illustrates a plan view of one embodiment of a processing system 500 illustrated in FIG. 5. With reference to FIG. 5 and FIG. 6, the processing system 500 comprises a transfer chamber 506 housing a substrate handler, a plurality of processing chambers coupled with the transfer chamber, such as a MOCVD chamber 502 and a HVPE chamber 504, a loadlock chamber 508 coupled with the transfer chamber 506, a batch loadlock chamber 509, for storing substrates, coupled with the transfer chamber 506, and a load station 510, for loading substrates, coupled with the loadlock chamber 508. The transfer chamber 506 comprises a robot assembly 530 operable to pick up and transfer substrates between the loadlock chamber 508, the batch loadlock chamber 509, the MOCVD chamber 502 and the HVPE chamber 504. The movement of the robot assembly 530 may be controlled by a motor drive system (not shown), which may include a servo or stepper motor.

Each processing chamber comprises a chamber body (such as element 512 for the MOCVD chamber 502 and element 514 for the HVPE chamber 504) forming a processing region where a substrate is placed to undergo processing, a chemical delivery module (such as element 516 for the MOCVD chamber 502 and element 518 for the HVPE chamber 504) from which gas precursors are delivered to the chamber body, and an electrical module (such as element 520 for the MOCVD chamber 502 and element 522 for the HVPE chamber 504) that includes the electrical system for each processing chamber of the processing system 500. The MOCVD chamber 502 is adapted to perform CVD processes in which metalorganic elements react with metal hydride elements to form thin layers of compound nitride semiconductor materials. The HVPE chamber 504 is adapted to perform HVPE processes in which gaseous metal halides are used to epitaxially grow thick layers of compound nitride semiconductor materials on heated substrates. In alternate embodiments, one or more additional chambers may 570 be coupled with the transfer chamber 506. These additional chambers may include, for example, anneal chambers, clean chambers for cleaning carrier plates, or substrate removal chambers. The structure of the processing system permits substrate transfers to occur in a defined ambient environment, including under vacuum, in the presence of a selected gas, under defined temperature conditions, and the like.

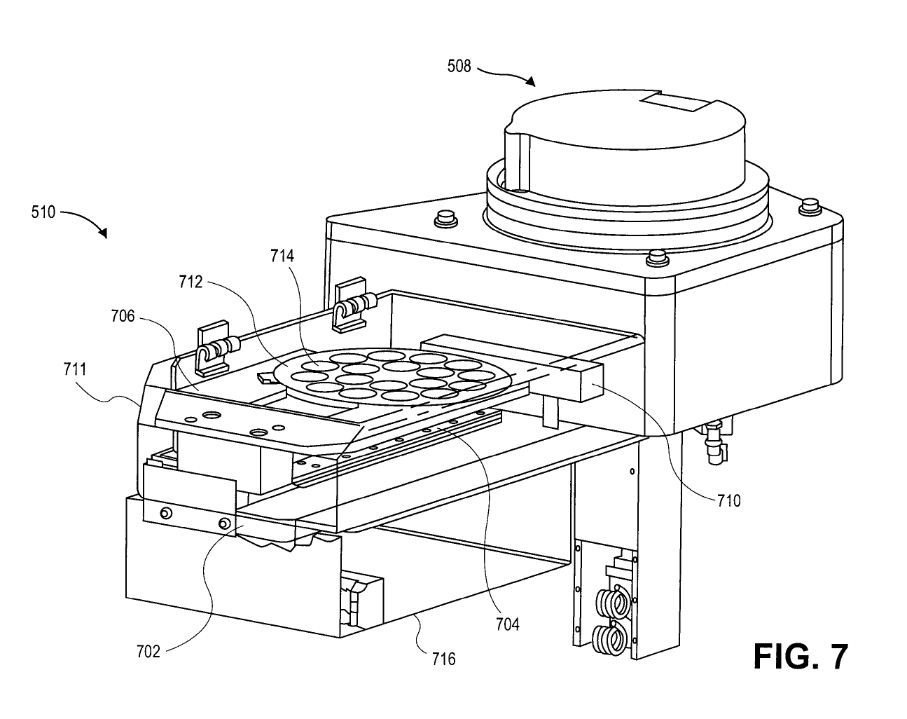

FIG. 7 is an isometric view illustrating a load station 510 and a loadlock chamber 508 according to an embodiment of the invention. The load station 510 is configured as an atmospheric interface to allow an operator to load a plurality of substrates for processing into the confined environment of the loadlock chamber 508, and unload a plurality of processed substrates from the loadlock chamber 508. The load station 510 comprises a frame 702, a rail track 704, a conveyor tray 706 adapted to slide along the rail track 704 to convey substrates into and out of the loadlock chamber 508 via a slit valve 710, and a lid 711. In one embodiment, the conveyor tray 706 may be moved along the rail track 704 manually by the operator. In another embodiment, the conveyor tray 706 may be driven mechanically by a motor. In yet another embodiment, the conveyor tray 706 is moved along the rail track 704 by a pneumatic actuator.

Substrates for processing may be grouped in batches and transported on the conveyor tray 706. For example, each batch of substrates 714 may be transported on a carrier plate 712 that can be placed on the conveyor tray 706. The lid 711 may be selectively opened and closed over the conveyor tray 706 for safety protection when the conveyor tray 706 is driven in movement. In operation, an operator opens the lid 711 to load the carrier plate 712 containing a batch of substrates on the conveyor tray 706. A storage shelf 716 may be provided for storing carrier plates containing substrates to be loaded. The lid 711 is closed, and the conveyor tray 706 is moved through the slit valve 710 into the loadlock chamber 508. The lid 711 may comprise a glass material, such as Plexiglas or a plastic material to facilitate monitoring of operations of the conveyor tray 706.

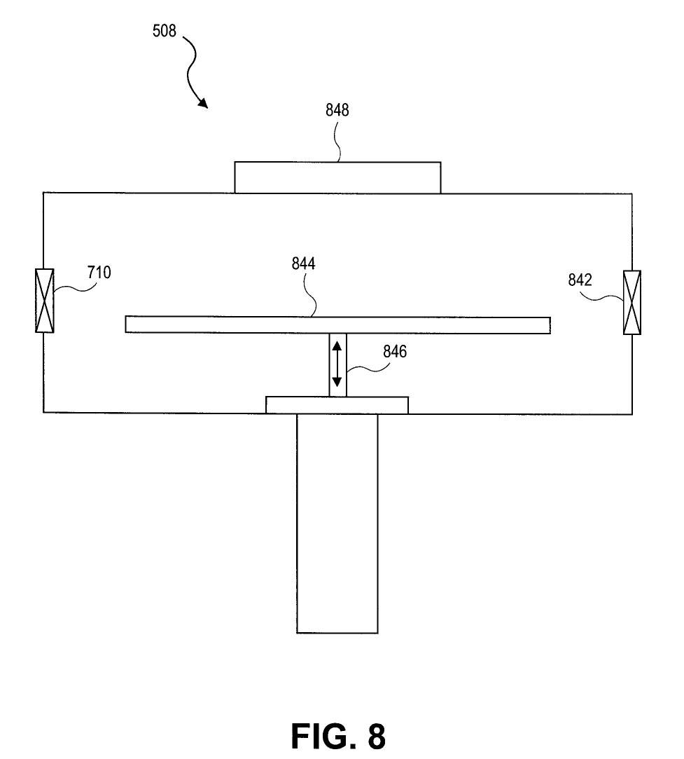

FIG. 8 is a schematic view of a loadlock chamber 508 according to an embodiment of the invention. The loadlock chamber 508 provides an interface between the atmospheric environment of the load station 510 and the controlled environment of the transfer chamber 506. Substrates are transferred between the loadlock chamber 508 and the load station 510 via the slit valve 710 and between the loadlock chamber 508 and the transfer chamber 506 via a slit valve 842. The loadlock chamber 508 comprises a carrier support 844 adapted to support incoming and outgoing carrier plates thereon. In one embodiment, the loadlock chamber 508 may comprise multiple carrier supports that are vertically stacked. To facilitate loading and unloading of a carrier plate, the carrier support 844 may be coupled to a stem 846 vertically movable to adjust the height of the carrier support 844. The loadlock chamber 508 is coupled to a pressure control system (not shown) which pumps down and vents the loadlock chamber 508 to facilitate passing the substrate between the vacuum environment of the transfer chamber 506 and the substantially ambient (e.g., atmospheric) environment of the load station 510. In addition, the loadlock chamber 508 may also comprise features for temperature control, such as a degas module 848 to heat substrates and remove moisture, or a cooling station (not shown) for cooling substrates during transfer. Once a carrier plate loaded with substrates has been conditioned in the loadlock chamber 508, the carrier plate may be transferred into the MOCVD chamber 502 or the HVPE chamber 504 for processing, or to the batch loadlock chamber 509 where multiple carrier plates are stored in standby for processing.

During operation, a carrier plate 712 containing a batch of substrates is loaded on the conveyor tray 706 in the load station 510. The conveyor tray 706 is then moved through the slit valve 710 into the loadlock chamber 508, placing the carrier plate 712 onto the carrier support 844 inside the loadlock chamber 508, and the conveyor tray returns to the load station 510. While the carrier plate 712 is inside the loadlock chamber 508, the loadlock chamber 508 is pumped and purged with an inert gas, such as nitrogen, in order to remove any remaining oxygen, water vapor, and other types of contaminants. After the batch of substrates have been conditioned in the loadlock chamber, the robot assembly 530 may transfer the carrier plate 712 to either the MOCVD chamber 502 or, the HVPE chamber 504 to undergo deposition processes. In alternate embodiments, the carrier plate 712 may be transferred and stored in the batch loadlock chamber 509 on standby for processing in either the MOCVD chamber 502 or the HVPE chamber 504. After processing of the batch of substrates is complete, the carrier plate 712 may be transferred to the loadlock chamber 508, and then retrieved by the conveyor tray 706 and returned to the load station 510.

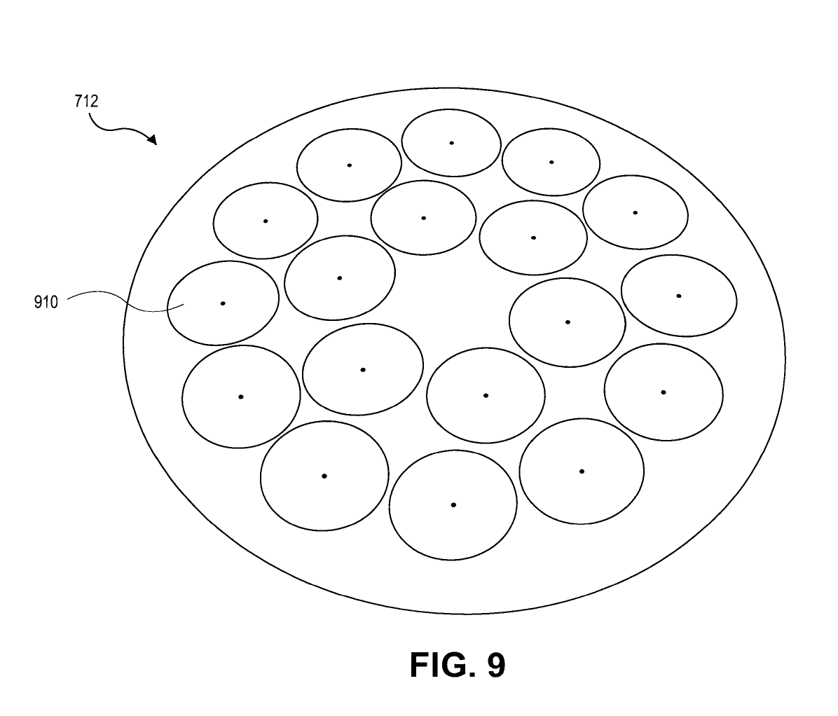

FIG. 9 is an isometric view of a carrier plate according to an embodiment of the invention. In one embodiment, the carrier plate 712 may include one or more circular recesses 910 within which individual substrates may be disposed during processing. The size of each recess 910 may be changed according to the size of the substrate to accommodate therein. In one embodiment, the carrier plate 712 may carry six or more substrates. In another embodiment, the carrier plate 712 carries eight substrates. In yet another embodiment, the carrier plate 712 carries 18 substrates. It is to be understood that more or less substrates may be carried on the carrier plate 712. Typical substrates may include sapphire, silicon carbide (SiC), silicon, or gallium nitride (GaN). It is to be understood that other types of substrates, such as glass substrates, may be processed. Substrate size may range from 50 mm-200 mm in diameter or larger. In one embodiment, each recess 910 may be sized to receive a circular substrate having a diameter between about 2 inches and about 6 inches. The diameter of the carrier plate 712 may range from 200 mm-750 mm, for example, about 300 mm. The carrier plate 712 may be formed from a variety of materials, including SiC, SiC-coated graphite, or other materials resistant to the processing environment. Substrates of other sizes may also be processed within the processing system 500 according to the processes described herein.

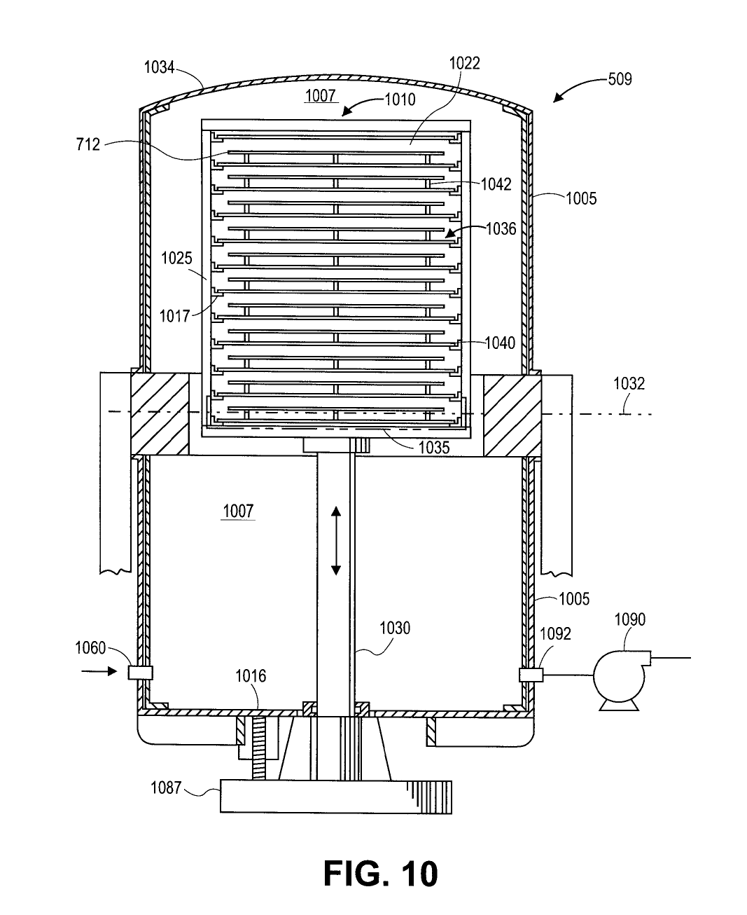

FIG. 10 is a schematic view of the batch loadlock chamber 509 according to an embodiment of the invention. The batch loadlock chamber 509 comprises a body 1005 and a lid 1034 and bottom 1016 disposed on the body 1005 and defining a cavity 1007 for storing a plurality of substrates placed on the carrier plates 712 therein. In one aspect, the body 1005 is formed of process resistant materials such as aluminum, steel, nickel, and the like, adapted to withstand process temperatures and is generally free of contaminates such as copper. The body 1005 may comprise a gas inlet 1060 extending into the cavity 1007 for connecting the batch loadlock chamber 509 to a process gas supply (not shown) for delivery of processing gases therethrough. In another aspect, a vacuum pump 1090 may be coupled to the cavity 1007 through a vacuum port 1092 to maintain a vacuum within the cavity 1007.

A storage cassette 1010 is moveably disposed within the cavity 1007 and is coupled with an upper end of a movable member 1030. The moveable member 1030 is comprised of process resistant materials such as aluminum, steel, nickel, and the like, adapted to withstand process temperatures and generally free of contaminates such as copper. The movable member 1030 enters the cavity 1007 through the bottom 1016. The movable member 1030 is slidably and sealably disposed through the bottom 1016 and is raised and lowered by the platform 1087. The platform 1087 supports a lower end of the movable member 1030 such that the movable member 1030 is vertically raised or lowered in conjunction with the raising or lowering of the platform 1087. The movable member 1030 vertically raises and lowers the storage cassette 1010 within the cavity 1007 to move the substrates carrier plates 712 across a substrate transfer plane 1032 extending through a window 1035. The substrate transfer plane 1032 is defined by the path along which substrates are moved into and out of the storage cassette 1010 by the robot assembly 530.

The storage cassette 1010 comprises a plurality of storage shelves 1036 supported by a frame 1025. Although in one aspect, FIG. 10 illustrates twelve storage shelves 1036 within storage cassette 1010, it is contemplated that any number of shelves may be used. Each storage shelf 1036 comprises a substrate support 1040 connected by brackets 1017 to the frame 1025. The brackets 1017 connect the edges of the substrate support 1040 to the frame 1025 and may be attached to both the frame 1025 and substrate support 1040 using adhesives such as pressure sensitive adhesives, ceramic bonding, glue, and the like, or fasteners such as screws, bolts, clips, and the like that are process resistant and are free of contaminates such as copper. The frame 1025 and brackets 1017 are comprised of process resistant materials such as ceramics, aluminum, steel, nickel, and the like that are process resistant and are generally free of contaminates such as copper. While the frame 1025 and brackets 1017 may be separate items, it is contemplated that the brackets 1017 may be integral to the frame 1025 to form support members for the substrate supports 1040.

The storage shelves 1036 are spaced vertically apart and parallel within the storage cassette 1010 to define a plurality of storage spaces 1022. Each substrate storage space 1022 is adapted to store at least one carrier plate 712 therein supported on a plurality of support pins 1042. The storage shelves 1036 above and below each carrier plate 712 establish the upper and lower boundary of the storage space 1022.

In another embodiment, substrate support 1040 is not present and the carrier plates 712 rest on brackets 1017.

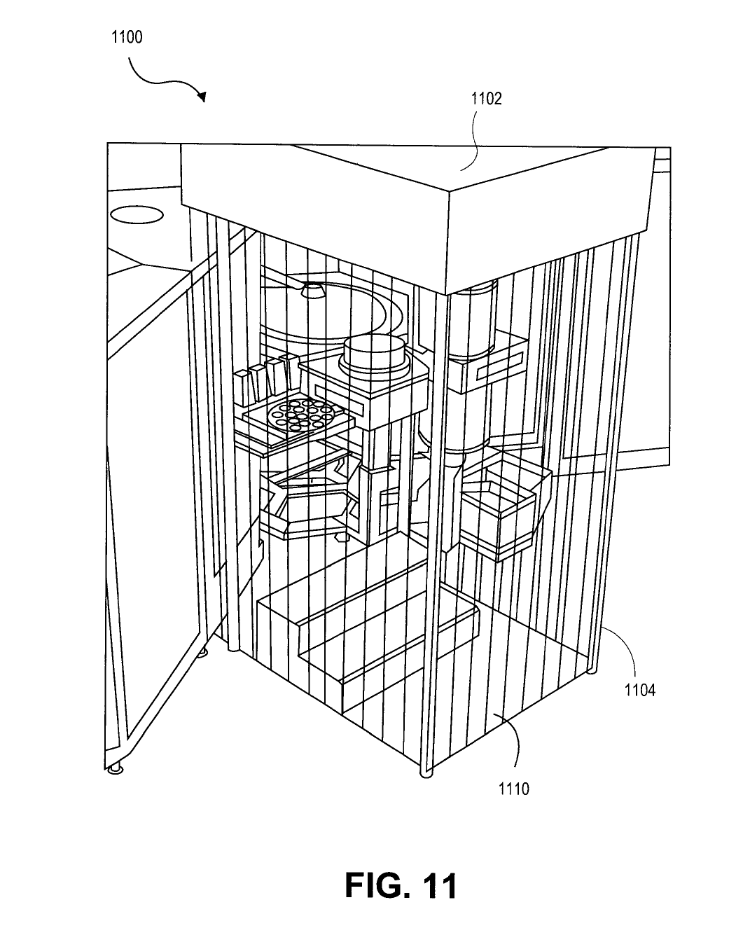

FIG. 11 is an isometric view of a work platform 1100 according to one embodiment of the invention. In one embodiment, the processing system 500 further comprises a work platform 1100 enclosing the load station 510. The work platform 1100 provides a particle free environment during loading and unloading of substrates into the load station 510. The work platform 1100 comprises a top portion 1102 supported by four posts 1104. A curtain 1110 separates the environment inside the work platform 1100 from the surrounding environment. In one embodiment, the curtain 1110 comprises a vinyl material. In one embodiment the work platform comprises an air filter, such as a High Efficiency Particulate Air Filter (“HEPA”) filter for filtering airborne particles from the ambient inside the work platform. In one embodiment, air pressure within the enclosed work platform 1100 is maintained at a slightly higher pressure than the atmosphere outside of the work platform 1100 thus causing air to flow out of the work platform 1100 rather than into the work platform 1100.

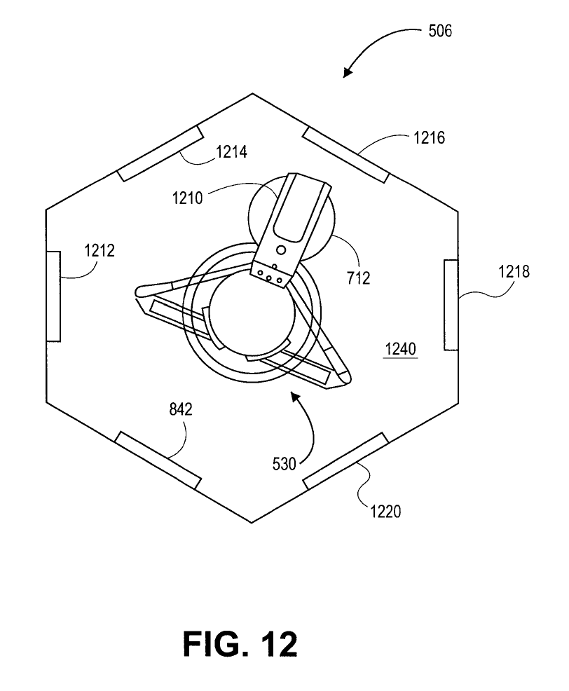

FIG. 12 is a plan view of a robot assembly 530 shown in the context of the transfer chamber 506. The internal region (e.g., transfer region 1240) of the transfer chamber 506 is typically maintained at a vacuum condition and provides an intermediate region in which to shuttle substrates from one chamber to another and/or to the loadlock chamber 508 and other chambers in communication with the cluster tool. The vacuum condition is typically achieved by use of one or more vacuum pumps (not shown), such as a conventional rough pump, Roots Blower, conventional turbo-pump, conventional cryo-pump, or combination thereof. Alternately, the internal region of the transfer chamber 506 may be an inert environment that is maintained at or near atmospheric pressure by continually delivering an inert gas to the internal region. Three such platforms are the Centura, the Endura and the Producer system all available from Applied Materials, Inc., of Santa Clara, Calif. The details of one such staged-vacuum substrate processing system are disclosed in U.S. Pat. No. 5,186,718, entitled “Staged-Vacuum Substrate Processing System and Method,” Tepman et al., issued on Feb. 16, 1993, which is incorporated herein by reference. The exact arrangement and combination of chambers may be altered for purposes of performing specific steps of a fabrication process.

The robot assembly 530 is centrally located within the transfer chamber 506 such that substrates can be transferred into and out of adjacent processing chambers, the loadlock chamber 508, and the batch loadlock chamber 509, and other chambers through slit valves 842, 1212, 1214, 1216, 1218, and 1220 respectively. The valves enable communication between the processing chambers, the loadlock chamber 508, the batch loadlock chamber 509, and the transfer chamber 506 while also providing vacuum isolation of the environments within each of the chambers to enable a staged vacuum within the system. The robot assembly 530 may comprise a frog-leg mechanism. In certain embodiments, the robot assembly 530 may comprise any variety of known mechanical mechanisms for effecting linear extension into and out of the various process chambers. A blade 1210 is coupled with the robot assembly 530. The blade 1210 is configured to transfer the carrier plate 712 through the processing systems. In one embodiment, the processing system 500 comprises an automatic center finder (not shown). The automatic center finder allows for the precise location of the carrier plate 712 on the robot assembly 530 to be determined and provided to a controller. Knowing the exact center of the carrier plate 712 allows the computer to adjust for the variable position of each carrier plate 712 on the blade and precisely position each carrier plate 712 in the processing chambers.

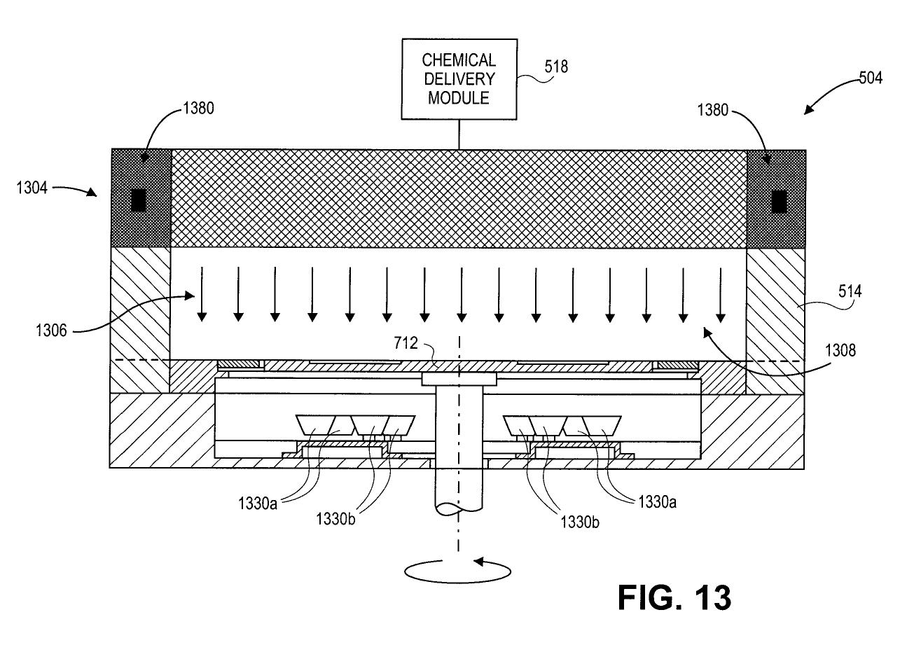

FIG. 13 is a schematic cross-sectional view of a HVPE chamber 504 according to an embodiment of the invention. The HVPE chamber 504 includes the chamber body 514 that encloses a processing volume 1308. A showerhead assembly 1304 is disposed at one end of the processing volume 1308, and the carrier plate 712 is disposed at the other end of the processing volume 1308. The showerhead assembly, as described above, may allow for more uniform deposition across a greater number of substrates or larger substrates than in traditional HVPE chambers, thereby reducing production costs. The showerhead may be coupled with a chemical delivery module 518. The carrier plate 712 may rotate about its central axis during processing. In one embodiment, the carrier plate 712 may be rotated at about 2 RPM to about 100 RPM. In another embodiment, the carrier plate 712 may be rotated at about 30 RPM. Rotating the carrier plate 712 aids in providing uniform exposure of the processing gases to each substrate.

A plurality of lamps 1330a, 1330b may be disposed below the carrier plate 712. For many applications, a typical lamp arrangement may comprise banks of lamps above (not shown) and below (as shown) the substrate. One embodiment may incorporate lamps from the sides. In certain embodiments, the lamps may be arranged in concentric circles. For example, the inner array of lamps 1330b may include eight lamps, and the outer array of lamps 1330a may include twelve lamps. In one embodiment of the invention, the lamps 1330a, 1330b are each individually powered. In another embodiment, arrays of lamps 1330a, 1330b may be positioned above or within showerhead assembly 1304. It is understood that other arrangements and other numbers of lamps are possible. The arrays of lamps 1330a, 1330b may be selectively powered to heat the inner and outer areas of the carrier plate 712. In one embodiment, the lamps 1330a, 1330b are collectively powered as inner and outer arrays in which the top and bottom arrays are either collectively powered or separately powered. In yet another embodiment, separate lamps or heating elements may be positioned over and/or under the source boat 1380. It is to be understood that the invention is not restricted to the use of arrays of lamps. Any suitable heating source may be utilized to ensure that the proper temperature is adequately applied to the processing chamber, substrates therein, and a metal source. For example, it is contemplated that a rapid thermal processing lamp system may be utilized such as is described in United States Patent Publication No. 2006/0018639, published Jan. 26, 2006, entitled PROCESSING MULTILAYER SEMICONDUCTORS WITH MULTIPLE HEAT SOURCES, which is incorporated by reference in its entirety.

In yet another embodiment, the source boat 1380 is remotely located with respect to the chamber body 514, as described in U.S. Provisional Patent Application Ser. No. 60/978,040, filed Oct. 5, 2007, titled METHOD FOR DEPOSITING GROUP III/V COMPOUNDS, which is incorporated by reference in its entirety.

One or more lamps 1330a, 1330b may be powered to heat the substrates as well as the source boat 1380. The lamps may heat the substrate to a temperature of about 900° C. to about 1200° C. In another embodiment, the lamps 1330a, 1330b maintain a metal source within the source boat 1380 at a temperature of about 350° C. to about 900° C. A thermocouple may be used to measure the metal source temperature during processing. The temperature measured by the thermocouple may be fed back to a controller that adjusts the heat provided from the heating lamps 1330a, 1330b so that the temperature of the metal source may be controlled or adjusted as necessary.

During the process according to one embodiment of the invention, precursor gases 1306 flow from the showerhead assembly 1304 towards the substrate surface. Reaction of the precursor gases 1306 at or near the substrate surface may deposit various metal nitride layers upon the substrate, including GaN, AN, and InN. Multiple metals may also be utilized for the deposition of “combination films” such as AlGaN and/or InGaN. The processing volume 1308 may be maintained at a pressure of about 760 torr down to about 100 torr. In one embodiment, the processing volume 1308 is maintained at a pressure of about 450 torr to about 760 torr. Exemplary embodiments of the showerhead assembly 1304 and other aspects of the HVPE chamber are described in U.S. patent application Ser. No. 11/767,520, filed Jun. 24, 2007, entitled HVPE TUBE SHOWERHEAD DESIGN, which is herein incorporated by reference in its entirety. Exemplary embodiments of the HVPE chamber 504 are described in U.S. Patent Application Ser. No. 61/172,630, filed Apr. 24, 2009, entitled HVPE CHAMBER HARDWARE, which is herein incorporated by reference in its entirety.

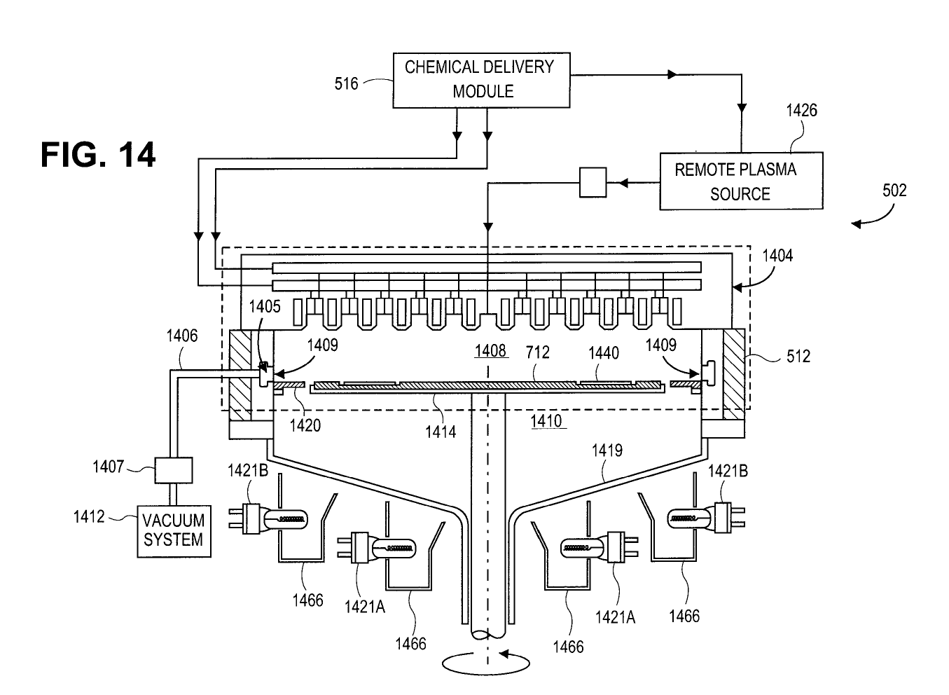

FIG. 14 is a schematic cross-sectional view of an MOCVD chamber according to an embodiment of the invention. The MOCVD chamber 502 comprises a chamber body 512, a chemical delivery module 516, a remote plasma source 1426, a substrate support 1414, and a vacuum system 1412. The chamber 502 includes a chamber body 512 that encloses a processing volume 1408. A showerhead assembly 1404 is disposed at one end of the processing volume 1408, and a carrier plate 712 is disposed at the other end of the processing volume 1408. The carrier plate 712 may be disposed on the substrate support 1414. Exemplary showerheads that may be adapted to practice the present invention are described in U.S. patent application Ser. No. 11/873,132, filed Oct. 16, 2007, entitled MULTI-GAS STRAIGHT CHANNEL SHOWERHEAD, U.S. patent application Ser. No. 11/873,141, filed Oct. 16, 2007, entitled MULTI-GAS SPIRAL CHANNEL SHOWERHEAD, and 11/873,170, filed Oct. 16, 2007, entitled MULTI-GAS CONCENTRIC INJECTION SHOWERHEAD, all of which are incorporated by reference in their entireties.

A lower dome 1419 is disposed at one end of a lower volume 1410, and the carrier plate 712 is disposed at the other end of the lower volume 1410. The carrier plate 712 is shown in process position, but may be moved to a lower position where, for example, the substrates 1440 may be loaded or unloaded. An exhaust ring 1420 may be disposed around the periphery of the carrier plate 712 to help prevent deposition from occurring in the lower volume 1410 and also help direct exhaust gases from the chamber 502 to exhaust ports 1409. The lower dome 1419 may be made of transparent material, such as high-purity quartz, to allow light to pass through for radiant heating of the substrates 1440. The radiant heating may be provided by a plurality of inner lamps 1421A and outer lamps 1421B disposed below the lower dome 1419 and reflectors 1466 may be used to help control the chamber 502 exposure to the radiant energy provided by inner and outer lamps 1421A, 1421B. Additional rings of lamps may also be used for finer temperature control of the substrates 1440.

A purge gas (e.g., nitrogen) may be delivered into the chamber 502 from the showerhead assembly 1404 and/or from inlet ports or tubes (not shown) disposed below the carrier plate 712 and near the bottom of the chamber body 512. The purge gas enters the lower volume 1410 of the chamber 502 and flows upwards past the carrier plate 712 and exhaust ring 1420 and into multiple exhaust ports 1409 which are disposed around an annular exhaust channel 1405. An exhaust conduit 1406 connects the annular exhaust channel 1405 to a vacuum system 1412 which includes a vacuum pump (not shown). The chamber 502 pressure may be controlled using a valve system 1407 which controls the rate at which the exhaust gases are drawn from the annular exhaust channel 1405. Other aspects of the MOCVD chamber are described in U.S. patent application Ser. No. 12/023,520, filed Jan. 31, 2008, (attorney docket no. 011977) entitled CVD APPARATUS, which is herein incorporated by reference in its entirety.

Various metrology devices, such as, for example, reflectance monitors, thermocouples, or other temperature devices may also be coupled with the chamber 502. The metrology devices may be used to measure various film properties, such as thickness, roughness, composition, temperature or other properties. These measurements may be used in an automated real-time feedback control loop to control process conditions such as deposition rate and the corresponding thickness. Other aspects of chamber metrology are described in U.S. Patent Application Ser. No. 61/025,252, filed Jan. 31, 2008, (attorney docket no. 011007) entitled CLOSED LOOP MOCVD DEPOSITION CONTROL, which is herein incorporated by reference in its entirety.

The chemical delivery modules 516, 518 supply chemicals to the MOCVD chamber 502 and HVPE chamber 504 respectively. Reactive and carrier gases are supplied from the chemical delivery system through supply lines into a gas mixing box where they are mixed together and delivered to respective showerheads 1404 and 1304. Generally supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and etchant gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

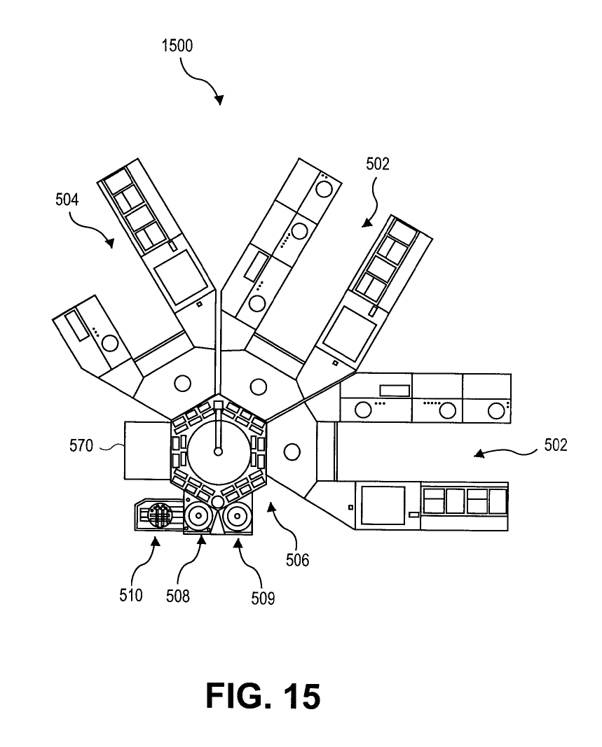

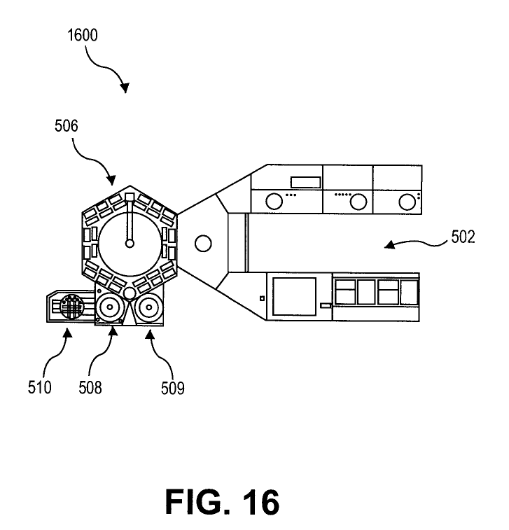

While the foregoing embodiments have been described in connection to a processing system that comprises one MOCVD chamber and one HVPE chamber, alternate embodiments may integrate one or more MOCVD and HVPE chambers in the processing system, as shown in FIGS. 15 and 16. FIG. 15 illustrates an embodiment of a processing system 1500 that comprises two MOCVD chambers 502 and one HVPE chamber 504 coupled to the transfer chamber 506. In the processing system 1500, the robot blade is operable to respectively transfer a carrier plate into each of the MOCVD chambers 502 and HVPE chamber 504. Multiple batches of substrates loaded on separate carrier plates thus can be processed in parallel in each of the MOCVD chambers 502 and HVPE chamber 504.

FIG. 16 illustrates a simpler embodiment of a processing system 1600 that comprises a single MOCVD chamber 502. In the processing system 1600, the robot blade transfers a carrier plate loaded with substrates into the single MOCVD chamber 502 to undergo deposition. After all the deposition steps have been completed, the carrier plate is transferred from the MOCVD chamber 502 back to the loadlock chamber 508, and then released toward the load station 510.

A system controller 560 controls activities and operating parameters of the processing system 500. The system controller 560 includes a computer processor and a computer-readable memory coupled to the processor. The processor executes system control software, such as a computer program stored in memory. Aspects of the processing system and methods of use are further described in U.S. patent application Ser. No. 11/404,516, filed Apr. 14, 2006, entitled EPITAXIAL GROWTH OF COMPOUND NITRIDE STRUCTURES, which is hereby incorporated by reference in its entirety.

The system controller 560 and related control software prioritize tasks and substrate movements based on inputs from the user and various sensors distributed throughout the processing system 500. The system controller 560 and related control software allow for automation of the scheduling/handling functions of the processing system 500 to provide the most efficient use of resources without the need for human intervention. In one aspect, the system controller 560 and related control software adjust the substrate transfer sequence through the processing system 500 based on a calculated optimized throughput or to work around processing chambers that have become inoperable. In another aspect, the scheduling/handling functions pertain to the sequence of processes required for the fabrication of compound nitride structures on substrates, especially for processes that occur in one or more processing chambers. In yet another aspect, the scheduling/handling functions pertain to efficient and automated processing of multiple batches of substrates, whereby a batch of substrates is contained on a carrier. In yet another aspect, the scheduling/handling functions pertain to periodic in-situ cleaning of processing chambers or other maintenance related processes. In yet another aspect, the scheduling/handling functions pertain to temporary storage of substrates in the batch loadlock chamber. In yet another aspect the scheduling/handling functions pertain to transfer of substrates to or from the load station based on operator inputs.

The following example is provided to illustrate how the general process described in connection with processing system 500 may be used for the fabrication of compound nitride structures. The example refers to a LED structure, with its fabrication being performed using a processing system 500 having at least two processing chambers, such as MOCVD chamber 502 and HVPE chamber 504. The cleaning and deposition of the initial GaN layers is performed in the HVPE chamber 504, with growth of the remaining InGaN, AlGaN, and GaN contact layers being performed in the MOCVD system 502.

The process begins with a carrier plate containing multiple substrates being transferred into the HVPE chamber 504. The HVPE chamber 504 is configured to provide rapid deposition of GaN. A pretreatment process and/or buffer layer is grown over the substrate in the HVPE chamber 504 using HVPE precursor gases. This is followed by growth of a thick n-GaN layer, which in this example is performed using HVPE precursor gases. In another embodiment the pretreatment process and/or buffer layer is grown in the MOCVD chamber and the thick n-GaN layer is grown in the HVPE chamber.

After deposition of the n-GaN layer, the substrate is transferred out of the HVPE chamber 504 and into the MOCVD chamber 502, with the transfer taking place in a high-purity N₂ atmosphere via the transfer chamber 506. The MOCVD chamber 502 is adapted to provide highly uniform deposition, perhaps at the expense of overall deposition rate. In the MOCVD chamber 502, the InGaN multi-quantum-well active layer is grown after deposition of a transition GaN layer. This is followed by deposition of the p-AlGaN layer and p-GaN layer. In another embodiment the p-GaN layer is grown in the HVPE chamber.

The completed structure is then transferred out of the MOCVD chamber 502 so that the MOCVD chamber 502 is ready to receive an additional carrier plate containing partially processed substrates from the HVPE chamber 504 or from a different processing chamber. The completed structure may either be transferred to the batch loadlock chamber 509 for storage or may exit the processing system 500 via the loadlock chamber 508 and the load station 510.

Before receiving additional substrates the HVPE chamber and/or MOCVD chamber may be cleaned via an in-situ clean process. The cleaning process may comprise etchant gases which thermally etch deposition from chamber walls and surfaces. In another embodiment, the cleaning process comprises a plasma generated by a remote plasma generator. Exemplary cleaning processes are described in U.S. patent application Ser. No. 11/404,516, filed on Apr. 14, 2006, and U.S. patent application Ser. No. 11/767,520, filed on Jun. 24, 2007, titled HVPE SHOWERHEAD DESIGN, both of which are incorporated by reference in their entireties.

An improved system and method for fabricating compound nitride semiconductor devices has been provided. In conventional manufacturing of compound nitride semiconductor structures, multiple epitaxial deposition steps are performed in a single process reactor, with the substrate not leaving the process reactor until all of the steps have been completed resulting in a long processing time, usually on the order of 4-6 hours. Conventional systems also require that the reactor be manually opened in order to remove and insert additional substrates. After opening the reactor, in many cases, an additional 4 hours of pumping, purging, cleaning, opening, and loading must be performed resulting in a total run time of about 8-10 hours per substrate. The conventional single reactor approach also prevents optimization of the reactor for individual process steps.

The improved system provides for simultaneously processing substrates using a multi-chamber processing system that has an increased system throughput, increased system reliability, and increased substrate to substrate uniformity. The multi-chamber processing system expands the available process window for different compound structures by performing epitaxial growth of different compounds in different processing having structures adapted to enhance those specific procedures. Since the transfer of substrates is automated and performed in a controlled environment, this eliminates the need for opening the reactor and performing a long pumping, purging, cleaning, opening, and loading process.

Thus, a method of forming LED structures has been described.

We claim:

1. A method of fabricating a semiconductor device comprising:
providing a substrate;
depositing a p type contact layer on the substrate at a high deposition temperature in a first processing chamber;
depositing an active region on top of the p type contact layer; and
depositing an n type contact layer on top of the active region at a low deposition temperature using a hydride vapor phase epitaxy (HVPE) process in a second processing chamber.

2. The method of claim 1, wherein the first processing chamber and the second processing chamber are processing chambers on a cluster tool having one or more processing chambers.

3. The method of claim 2, further comprising transferring the substrate between the processing chambers of the cluster tool without breaking vacuum.

4. The method of claim 1, wherein the substrate is selected from the group consisting of a sapphire substrate, a silicon carbide substrate, a silicon on diamond substrate, a quartz substrate, a glass substrate, a zinc oxide substrate, a magnesium oxide substrate, a lithium a gallium oxide substrate, and a lithium aluminum oxide substrate.

5. The method of claim 1, wherein the high deposition temperature is greater than 1000° C.

6. The method of claim 1, wherein the low deposition temperature is less than 950° C.

7. The method of claim 1, wherein the p type contact layer is a Group III-Nitride doped with a p type dopant.

8. The method of claim 7, wherein the p type dopant comprises an element having at least two valence electrons.

9. The method of claim 8, wherein the p type dopant is selected from the group consisting of Mg, Be, Ca, and Sr.

10. The method of claim 1, wherein the n type contact layer is a Group III-Nitride doped with an n type dopant.

11. The method of claim 10, wherein the n type dopant is selected from the group consisting of Si, Ge, Sn, and Pb.

12. The method of claim 1, further comprising depositing a buffer layer on top of the substrate.

13. The method of claim 1, wherein the buffer layer is an undoped GaN film.

14. A method of fabricating a semiconductor device comprising:
providing a substrate;
depositing a n type contact layer;
depositing an active region;
depositing a p type contact layer using a hydride vapor phase epitaxy (HVPE) process;
depositing a p+ layer using the HVPE process in a first processing chamber, wherein the p+ layer is in contact with the p type contact layer creating an abrupt p/p+ doping profile;
depositing an n+ layer in a second processing chamber, wherein the n+ layer is in contact with the p+ layer creating an abrupt n+/p+ doping profile; and
depositing an n type tunnel junction contact layer.

15. The method of claim 14, wherein the first processing chamber and the second processing chamber are processing chamber on a cluster tool having one or more processing chambers.

16. The method of claim 15, further comprising transferring the substrate between the processing chambers of the cluster tool without breaking vacuum.

17. The method of claim 14, wherein the substrate is selected from the group consisting of a sapphire substrate, a silicon carbide substrate, a silicon on diamond substrate, a quartz substrate, a glass substrate, a zinc oxide substrate, a magnesium oxide substrate, a lithium gallium oxide substrate, and a lithium aluminum oxide substrate.

18. The method of claim 14, wherein the n type contact layer is deposited on top the substrate, the active region is deposited on top of the n type contact layer, the p type contact layer is deposited on top of the active region, the p+ layer is deposited on top of the p type contact layer, the n+ layer is deposited on top of the p+ layer, and the n type tunnel junction contact layer is deposited on top of the n+ layer.

19. The method of claim 14, wherein the n type tunnel junction contact layer is deposited on top of the substrate, the n+ layer is deposited on top of the n type tunnel junction contact layer, the p+ layer is deposited on top of the n+ layer, the p type contact layer is deposited on top of the p+ layer, the active region is deposited on top of the p type contact layer, the n type contact layer is deposited on top of the active region.

20. The method of claim 14, wherein the n+ layer and the p+ layer are doped to a conductivity level greater 1×10¹⁹ atoms/cm³.

21. The method of claim 14, wherein the n+ layer and the p+ layer are formed to a thickness between 1.0 nanometers and 20.0 nanometers.

22. The method of claim 14, wherein the p+ layer is a Group III-Nitride doped with a p type dopant.

23. The method of claim 22, wherein the p type dopant comprises an element having at least two valence electrons.

24. The method of claim 23, wherein the p type dopant is selected from the group consisting of Mg, Be, Ca, and Sr.

25. The method of claim 14, wherein the n type tunnel junction contact layer is a Group III-Nitride doped with an n type dopant.

26. The method of claim 25, wherein the n type dopant is selected from the group consisting of Si, Ge, Sn, and Pb.

27. The method of claim 14, wherein the p type contact layer is a Group III-Nitride doped with a p type dopant.

28. The method of claim 27, wherein the p type dopant comprises an element having at least two valence electrons.

29. The method of claim 28, wherein the p type dopant is selected from the group consisting of Mg, Be, Ca, and Sr.
